(19) United States
(12) Patent Application Publication
(10) Pub. No.: US 2012/0257761 A1
(43) Pub. Date: Oct. 11, 2012

(54) APPARATUS AND METHOD FOR AUTO ADJUSTMENT OF VOLUME IN A PORTABLE TERMINAL

(75) Inventor: Arun KUMAR, Noida (IN)

(73) Assignee: SAMSUNG ELECTRONICS CO. LTD., Suwon-si (KR)

(21) Appl. No.: 13/443,218

(22) Filed: Apr. 10, 2012

(30) Foreign Application Priority Data
Apr. 11, 2011 (IN) 1246/CHE/2011
Mar. 23, 2012 (KR) 10-2012-0030097

(51) Int. Cl. H03G 3/20

(52) U.S. Cl. 381/57

(57) ABSTRACT

An apparatus and a method for automatically adjusting the volume in an electronic device are provided. The apparatus includes a loud-speaker for controlling a volume of the speaker and a volume of the listener, a microphone for controlling the volume of the speaker, and a noise sensor for determining an environment of the speaker and an environment of the listener.

### PRIORITY

This application claims the benefit under 35 U.S.C. §119(a) of an Indian Provisional patent application filed in the Indian Intellectual Property Office on Apr. 11, 2011 and assigned Serial No. 1246/CHE/2011 and of a Korean patent application filed in the Korean Intellectual Property Office on Mar. 23, 2012 and assigned Serial No. 10-2012-0030097, the entire disclosure of each of which is hereby incorporated by reference.

### BACKGROUND OF THE INVENTION

1. Field of the Invention

The present invention relates to a portable terminal. More particularly, the present invention relates to an apparatus and method for automatically adjusting the volume in a portable terminal.

2. Description of the Related Art

A portable terminal is widely used for a variety of applications such as, making a telephone call, receiving a telephone call, accessing the interne, accessing an email account, short range wireless communications such as Bluetooth and infrared, supporting multiple accessories such as Short Message Service (SMS), Multi-media Messaging Service (MMS), games, global positioning requirements, and the like.

The portable terminal, which is primarily used for communication between two users, may be exposed to various noises during its use. Examples of such various noises include, but are not limited to, a crowded environment, road traffic, industrial noise, and the like. In the presence of such noise, a user may have difficulty hearing the voice the other user over the portable terminal The presence of such noise can be regarded as an ambient noise.

To address the issue of ambient noise, a portable terminal may include a volume control system for overcoming the ambient noise and for controlling the volume of the speaker and the listener during conversation over the portable terminal. Further, a volume control system embedded in a portable terminal is responsible for providing clarity of speech to a listener while a speaker is talking on the other side.

A volume control system of the related art alters the volume of the speaker and the listener relative to the change in noise environments. That is, the volume control system of the related art amplifies the volume of the speaker when the speaker is present in a noisy environment. The amplification of the volume enables the listener to hear the voice of the speaker despite the presence of noise in the environment of the speaker. However, the volume control system of the related art does not take into account if the speaker is present in a noiseless environment such as a conference room, a hospital, and the like. If the speaker is present in such an environment, then the speaker tends to talk with a low-volume. However, the low-volume of the speaker restrains the listener from hearing the voice of the speaker distinctly. Further, the volume control system of the related art does not take into account when the listener is in a noisy environment. If the listener is present in the noisy environment, it is difficult for the listener to hear the voice of the speaker. Such noiseless environments and noisy environments can be regarded as special ambient noise conditions. Hence, controlling the voice of the speaker and the listener under special ambient conditions is desired.

In light of the foregoing discussion, there is a need for an efficient method and system for controlling the volume of the speaker and the listener under special ambient noise conditions.

### SUMMARY OF THE INVENTION

Aspects of the present invention are to address at least the above-mentioned problems and/or disadvantages and to provide at least the advantages described below. Accordingly, an aspect of the present invention is to provide an apparatus and method for automatically adjusting the volume in a portable terminal.

In accordance with an aspect of the present invention, an apparatus for automatically adjusting the volume in an electronic device is provided. The apparatus includes a loud-speaker for adjusting a volume of a speaker and a volume of a listener, a microphone for adjusting the volume of the speaker, and a noise sensor for determining an environment of the speaker and an environment of the listener.

In accordance with another aspect of the present invention, a method for automatically adjusting the volume in an electronic device is provided. The method includes receiving an input from a user, determining an environment of a speaker and an environment of a listener, and selecting one of a plurality of options for controlling a volume of the speaker and a volume of the listener based on the determined environment of the speaker and the determined environment of the listener.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 is a block diagram of a volume adjustment apparatus for controlling the volume of a speaker and a listener under special ambient noise conditions according to an exemplary embodiment of the present invention.

FIG. 2 is a flowchart illustrating a method for controlling the volume of a speaker and a listener under special ambient noise conditions according to an exemplary embodiment of the present invention.

FIG. 3 is a flowchart illustrating a method for controlling volume when a first user is in a noisy environment according to an exemplary embodiment of the present invention.

FIG. 4 is a flowchart illustrating a method for controlling volume when a first user is in a low-noise environment according to an exemplary embodiment of the present invention.

FIG. 5 is a flowchart illustrating a method for controlling volume when a second user is in a noisy environment according to an exemplary embodiment of the present invention.

FIG. 6 is a flowchart illustrating a method for controlling volume when a second user is in a low-noise environment according to an exemplary embodiment of the present invention.

Throughout the drawings, it should be noted that like reference numbers are used to depict the same or similar elements, features, and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

In accordance with exemplary embodiments of the present invention, a portable terminal is an electronic device that allows for easy carriage. The term “portable terminal” covers a broad range of terminals including a video phone, a portable phone, a smart phone, an International Mobile Telecommunication 2000 (IMT-2000) terminal, a Wideband Code Division Multiple Access (WCDMA) terminal, a Universal Mobile Telecommunication System (UMTS) terminal, a Personal Digital Assistant (PDA), a Portable Multimedia Player (PMP), a Digital Multimedia Broadcasting (DMB) terminal, an e-book reader, a portable computer such as a laptop, a tablet, etc., a digital camera, and the like.

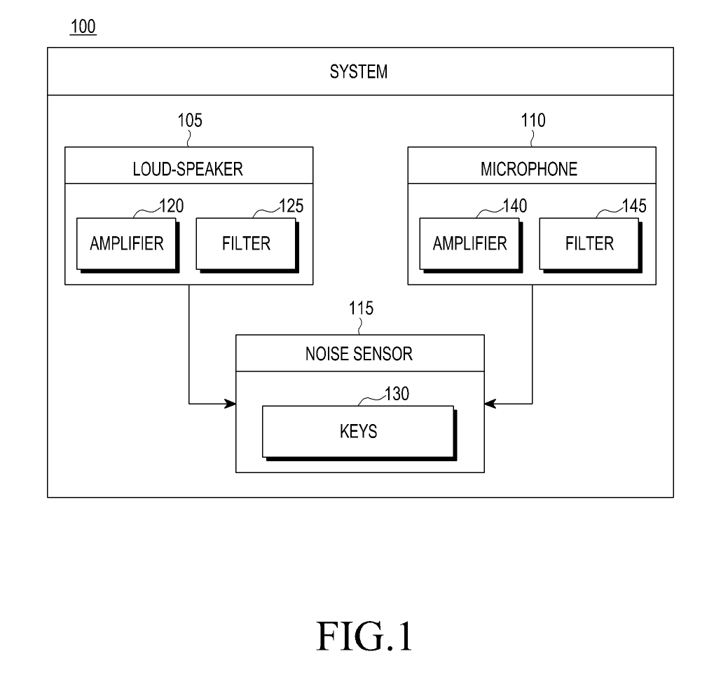

FIG. 1 is a block diagram of a volume adjustment apparatus for controlling the volume of a speaker and a listener under special ambient noise conditions according to an exemplary embodiment of the present invention.

Referring to FIG. 1, the volume adjustment apparatus 100 includes a loud-speaker 105, a microphone 110, and a noise sensor 115.

The volume adjustment apparatus 100 may be embedded in an electronic device such as a portable terminal. The loudspeaker 105 may be utilized to amplify the voice of a speaker so that a listener can distinctly hear the voice of the speaker. In this case, the term “listener” refers to the user of the portable terminal that includes the volume adjustment apparatus 100 and the term “speaker” refers a remote user who has transmitted a voice signal to the listener. The loud-speaker 105 further includes an amplifier 120 and a filter 125.

The amplifier 120 may be utilized to amplify the voice of the speaker. Further, the amplifier 120 included in the loud-speaker 105 may be utilized to amplify the voice of the speaker when the listener is in a noisy environment. Amplifying the voice of the speaker when the listener is in the noisy environment increases the volume of the speaker. Increasing the volume of the speaker enables the listener to better hear the voice of the speaker despite being present in the noisy environment.

Furthermore, the amplifier 120 included in the loud-speaker 105 may be utilized to amplify the voice of the speaker when the speaker is in a noisy environment. Amplifying the voice of the speaker when the speaker is present in the noisy environment increases the volume of the speaker and enables the listener to better hear the voice of the speaker.

The filter 125 may be utilized to filter the noise present in the noisy environment of the speaker. The filter 125 included in the loud-speaker 105 may filter the noise present in the noisy environment by allowing merely the voice of the speaker to pass through the filter. As an example, the filter 125 may be configured to transmit speech signals bearing a speech frequency. The filter 125 may also be configured to eliminate noise bearing a frequency that is unlike the speech frequency. In one example, if the speaker is present in the noisy environment, the filter 125 filters the noise that is present in the noisy environment. Further, the filter 125 transmits the voice of the speaker exclusively thereby enabling the listener to hear the voice of the speaker in a distinct manner.

The microphone 110 may be utilized to ensure that the voice of the speaker is distinctly heard by the listener. In this case, the term “speaker” refers to the user of the portable terminal that includes the volume adjustment apparatus 100 and the term “listener” refers a remote user who will receive a voice signal transmitted by the listener. The microphone 110 further may include an amplifier 140 and a filter 145. The amplifier 140 and the filter 145 may be similar in construction and operation to the amplifier 120 and filter 125 included in the loud-speaker 105.

The amplifier 140 included in the microphone 110 may be utilized to amplify the voice of the speaker. In one example, if the speaker is in a low noise environment such as a hospital, the speaker tends to speak with a low-volume. However, the low-volume of the speaker makes it difficult for the listener to hear the voice of the speaker. Hence the amplifier 140 included in the microphone 110 may be utilized to amplify the voice of the speaker. Amplifying increases the volume of the voice of the speaker thereby ensuring that the voice of the speaker is heard distinctly by the listener.

The filter 145 included in the microphone 110 may be utilized to filter the noise present in a noisy environment. The noisy environment may correspond to the speaker. Further, the noisy environment may be correspond to the listener. The filter 145 included in the microphone 110 reduces noise present in the noisy environment. Further, the filter 145 included in the microphone 110 ensures that voice of the speaker is transmitted exclusively. The exclusive transmission of voice of the speaker enables the listener to more distinctly hear the voice of the speaker.

The volume adjustment apparatus 100 further includes the noise sensor 115. The noise sensor 115 may be utilized to determine the environment associated with the speaker and the listener. In one example, the noise sensor 115 may determine that the speaker is associated with the noisy environment. In another example, the noise sensor 115 may determine that the speaker is associated with the low noise environment. In yet another example, the noise sensor 115 may determine that the listener is associated with the noisy environment. Further, in another example, the noise sensor 115 may determine that the listener is associated with the low noise environment.

The noise sensor 115 identifies various types of noise present in the environment of the speaker and the listener. Further, the type of the environment associated with a user may be specified by the user themselves. In this case, the user may be regarded as either the speaker or the listener. The noise sensor 115 includes keys 130 that may be utilized by the user to specify the type of the environment in which the user is located. The keys 130 may include one or more buttons. The one or more buttons included in the keys 130 may be utilized for accepting an input provided by the user. The input provided by the user may specify the type of environment such as the noisy environment, the low noise environment, and the like.

Further, the keys 130 can be constructed as hardware, but can also be implemented as software. For example, when a display unit (not shown) of the portable terminal is implemented in a touch display screen manner such as a capacitive or a resistive type screen, the display unit (not shown) can replace a part of key input functions of the keys 130.

Similarly, a function performed by the noise sensor 115 can be also executed in a microprocessor (not shown) in the portable terminal. For example, the microprocessor (not shown) can identify various types of noises existing in the environments of the speaker and the listener. Further, the microprocessor (not shown) can output lists of environment types which can be designated by the user, and determine an environment selected by the user from a plurality of environments included in the output lists as a user's environment.

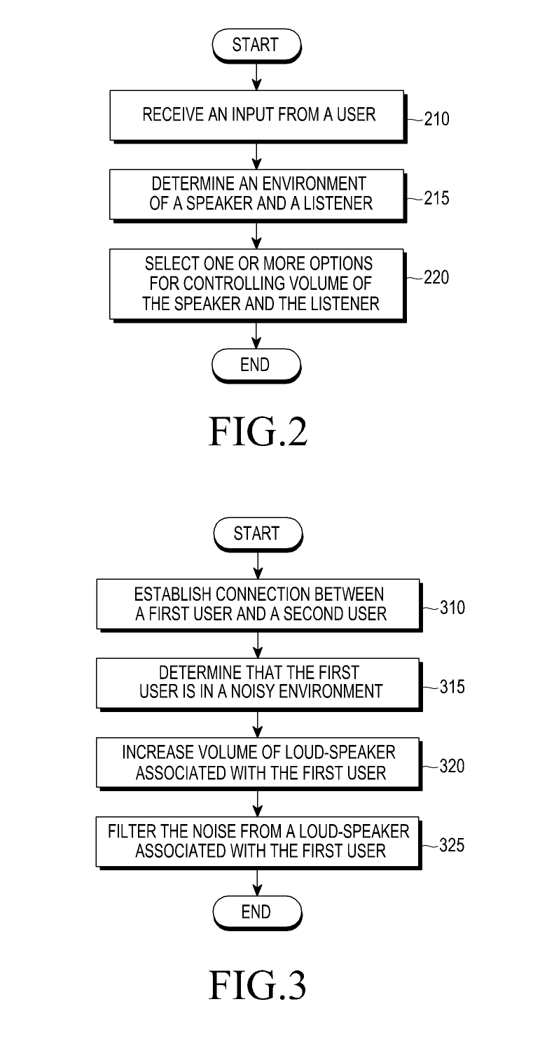

FIG. 2 is a flowchart illustrating a method for controlling the volume of a speaker and a listener of an electronic device according to an exemplary embodiment of the present invention.

Referring to FIG. 2, the portable terminal receives an input from a user at step 210. The user may be regarded as a speaker. Further, the user may be regarded as a listener. The speaker and the listener may be communicating with each other using a portable terminal The input received from the user specifies an environment of the user such as a noisy environment, a low-noise environment, a normal environment, and the like.

The input provided by the user may be utilized for configuring the volume adjustment apparatus 100 for controlling the volume of the speaker and the volume of the listener. The volume of the speaker and the volume of the listener may be controlled based on the input provided by the user.

At step 215, the portable terminal determines the environment associated with the speaker and the environment associated with the listener. Either environment may be determined using a noise sensor 115. As an example, the determined environments may include the speaker being associated with a noisy environment and the listener being associated with a normal environment. Further, the determined environments may also include the speaker being associated with a low-noise environment and the listener being associated with a normal environment. Furthermore, the determined environments may include the speaker being associated with a normal environment and the listener being associated with a noisy environment. Moreover, the determined environments may also include the speaker being associated with a normal environment and the listener being associated with a low-noise environment. Of course, the listener and the speaker may each be associated with any type of noise environment.

The volume of the speaker and the volume of the listener may be controlled based on the determined environment. The controlling of the volume based on the determined environment are explained in more detail below.

At step 220, the portable terminal selects one or more options for controlling the volume of the speaker and the volume of the listener. The one or more options may define one or more solutions to control the volume of the speaker and the volume of the listener. The one or more options defining the one or more solutions may be selected based on the environment determined at step 215. The one or more solutions for controlling the volume of the speaker and the volume of the listener are explained in more detail with reference to FIGS. 3-6.

FIG. 3 is a flowchart illustrating a method for controlling volume when a first user is in a noisy environment according to an exemplary embodiment of the present invention.

Referring to FIG. 3, the portable terminal establishes a connection between a first user and a second user at step 310. In one example, the first user may be regarded as a speaker and the second user may be regarded as the listener. The speaker and the listener may be communicating with each other using, in one example, a portable terminal. Further, it may be assumed that a volume adjustment apparatus 100 may be embedded in the portable terminal utilized by the first user.

At step 315, the portable terminal determines that the speaker is present in a noisy environment. Further, the portable terminal determines that the listener is present in a normal environment. Because the speaker is present in the noisy environment during the conversation, it is difficult for the listener to hear the voice of the speaker. The determination of the speaker being present in the noisy environment may be performed using a noise sensor 115. As an alternative, the speaker may provide an input to the volume adjustment apparatus 100 signifying that the speaker is present in the noisy environment.

Upon determining that the speaker is present in the noisy environment, the portable terminal increases the volume of a loud-speaker 105 included in the volume adjustment apparatus 100 at step 320. The volume of the loud-speaker may be increased using an amplifier 120 included in loud-speaker 105. The amplifier may amplify the voice of the speaker. Amplification results in increasing the volume of the speaker so that the listener may distinctly hear the voice of the speaker although the speaker is present in the noisy environment.

At step 325, the portable terminal filters the noise present in the noisy environment that is associated with the speaker. The noise is filtered so that the voice of the speaker is distinctly heard by the listener. A filter 125 may be embedded in the loud-speaker 105 in order to filter the noise present in the noisy environment. Further, at step 325, the portable terminal outputs the voice of the speaker after reducing the noise surrounding the speaker through the loud-speaker 105.

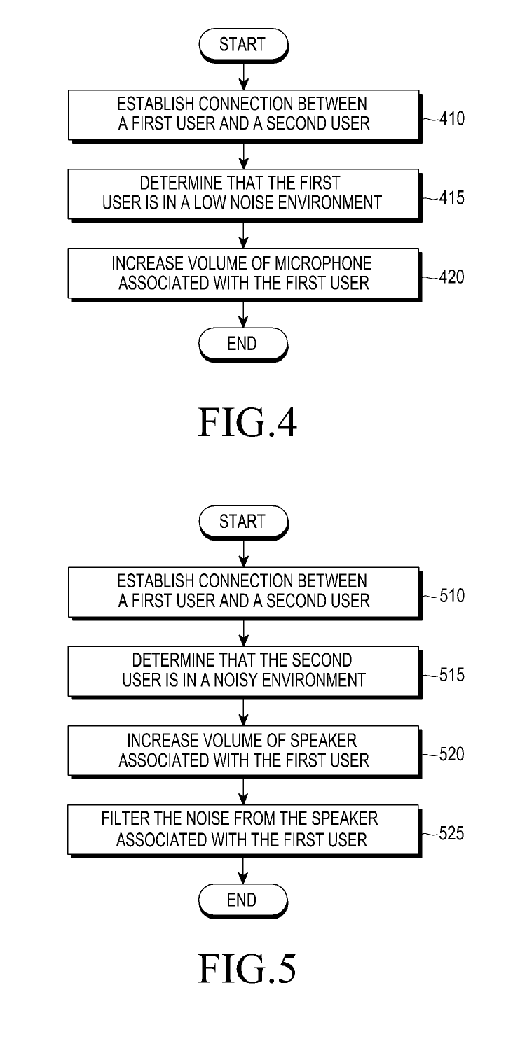

FIG. 4 is a flowchart illustrating a method for controlling volume when a first user is in a low noise environment according to an exemplary embodiment of the present invention.

Referring to FIG. 4, the portable terminal establishes a connection between a first user and a second user at step 410. In one example, the first user may be regarded as a speaker and the second user may be regarded as the listener. The speaker and the listener may be communicating with each other using, in one example, a portable terminal. Further, it may be assumed that a volume adjustment apparatus 100 may be embedded in the portable terminal utilized by the first user.

At step 415, the portable terminal determines that the speaker or the first user is present in a low-noise environment such as a hospital, a conference room, and the like. Further, the portable terminal determines that the listener is present in a normal environment. Because the speaker is present in the low-noise environment during the conversation, the speaker will tend to talk with a low-volume. And, because the speaker is talking with the low-volume, it is difficult for the listener to hear the voice of the speaker. The determination that the speaker is present in the low-noise environment may be performed using a noise sensor 115. As an alternative, the speaker may provide an input to the volume adjustment apparatus 100 signifying that the speaker is present in the low-noise environment.

Upon determining that the speaker is present in the low-noise environment, the portable terminal increases the volume of a microphone 110 embedded in the volume adjustment apparatus 100 at step 420. The volume may be increased in order that the listener is able to hear the voice of the speaker more distinctly despite the speaker talking with a low-volume. The volume of the microphone 110 may be increased using an amplifier 140. The amplifier 140 may be utilized to amplify the voice of the speaker, thereby allowing the listener to hear the voice of the speaker although the speaker is talking with a low volume.

FIG. 5 is a flowchart illustrating a method for controlling volume when a second user is in a noisy environment according to an exemplary embodiment of the present invention.

Referring to FIG. 5, the portable terminal establishes a connection between a first user and a second user at step 510. The first user and the second user may be communicating with each other using, in one example, a portable terminal Further, it may be assumed that a volume adjustment apparatus 100 may be embedded in the portable terminal utilized by the first user.

At step 515, the portable terminal determines that the second user is present in a noisy environment. Further, the portable terminal determines that the first user is present in a normal environment. Because the second user is present in the noisy environment during the conversation, it is difficult for the first user to hear the voice of the second user. Further, the first user may hear the noise present from the noisy environment rather than hear the voice of the second user which is undesirable during the conversation.

The determination that the second user is present in the noisy environment may be performed using a noise sensor 115. The noise sensor 115 may be embedded in the volume adjustment apparatus 100. Further, the first user may provide an input to the volume adjustment apparatus 100 signifying that the second user is present in the noisy environment. The first user provides the input as the volume adjustment apparatus 100 is embedded in the portable terminal utilized by the first user. Similarly, a volume adjustment apparatus 100 can be embedded in the portable terminal utilized by the second user as well.

Upon determining that the second user is in the noisy environment, the portable terminal increases the volume of the loud-speaker 105 included in the volume adjustment apparatus 100 at step 520. The volume of the loud-speaker 105 may be increased so that the voice of the second user may be heard more distinctly by the first user. Further, the volume of the loud-speaker may be increased using an amplifier 120 included in loud-speaker 105. The amplifier 120 may amplify the voice of the second user. Amplification increases the volume of the second user so that the first user may hear voice of the second user more distinctly although the second user is present in the noisy environment.

At step 525, the portable terminal filters the noise present in the noisy environment that is associated with the second user. The noise is filtered so that the voice of the second user is heard more distinctly by the first user. A filter 125 may be included in the loud-speaker 105 in order to filter the noise present in the noisy environment. Further at step 525, the portable terminal outputs the voice of the second user after addressing the noise surrounding the second user through the loud-speaker 105.

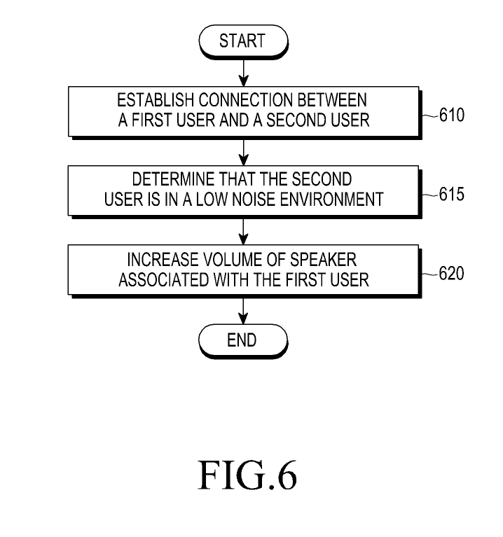

FIG. 6 is a flowchart illustrating a method for controlling volume when a second user is in a low noise environment according to an exemplary embodiment of the present invention.

Referring to FIG. 6, the portable terminal establishes a connection between a first user and a second user at step 610. The first user and the second user may be communicating with each other using, in one example, a portable terminal Further, it may be assumed that a volume adjustment apparatus 100 may be embedded in the portable terminal utilized by the first user.

At step 615, the portable terminal determines that the second user is present in a low-noise environment such as a hospital, a conference room, and the like. Further, the portable terminal determines that the first user is present in a normal environment. Because the second-user is present in the low-noise environment during the conversation, the second-user tends to talk with a low-volume. The second-user talking with the low-volume restrains the first user from hearing the voice of the second user.

The determination that the second user is present in the low-noise environment may be performed using a noise sensor 115. The noise sensor 115 may be embedded with the volume adjustment apparatus 100. Further, the first user may provide an input to the volume adjustment apparatus 100 signifying that the second user is present in the low-noise environment. The input may be provided by the first user as the volume adjustment apparatus 100 is embedded in the portable terminal utilized by the first user. Similarly, the volume adjustment apparatus 100 can be embedded in the portable terminal utilized by the second user as well.

Upon determining that the second user is present in the low-noise environment, the portable terminal increases the volume of the loud-speaker 105 included in the volume adjustment apparatus 100 at step 620. The volume may be increased in order to hear the voice of the second user more distinctly by the first user although the second user is talking with low-volume. The volume of the loud-speaker 105 may be increased using an amplifier 125. The amplifier 125 may be utilized to amplify the voice of the second user. Amplification increases the volume of the voice of the second user, thereby allowing the first user to hear voice of the second user more distinctly although the second user is talking with low volume.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. An apparatus for automatically adjusting the volume in an electronic device, the apparatus comprising:
a loud-speaker for controlling a volume of a speaker and a volume of a listener;
a microphone for controlling the volume of the speaker; and
a noise sensor for determining an environment of the speaker and an environment of the listener.

2. The apparatus of claim 1, wherein the loud-speaker comprises an amplifier for amplifying the volume of the speaker and the volume of the listener.

3. The apparatus of claim 1, wherein the loud-speaker comprises a filter for filtering noise present in the environment of the speaker and for filtering noise present in the environment of the listener.

4. The apparatus of claim 1, wherein the microphone comprises an amplifier for increasing the volume of the speaker.

5. The apparatus of claim 1, wherein the microphone comprises a filter for filtering noise present in the environment of the listener.

6. The apparatus of claim 1, wherein the noise sensor comprises one or more keys for accepting an input from a user of the electronic device.

7. The apparatus of claim 6, wherein the user is one of the speaker and the listener.

8. The apparatus of claim 6, wherein the input comprises information associated with the environment of the speaker and the environment of the listener.

9. A method for automatically adjusting the volume in an electronic device, the method comprising:
receiving an input from a user;
determining an environment of the speaker and an environment of the listener based on the input; and
selecting one of a plurality of options for controlling a volume of the speaker and a volume of the listener based on the determined environment of the speaker and the determined environment of the listener.

10. The method of claim 9, wherein the input comprises information associated with at least one of the environment of the speaker and the environment of the listener.

11. The method of claim 9, wherein the user is one of the speaker and the listener.

12. The method of claim 10, wherein the environment of the speaker comprises high noise.

13. The method of claim 12, further comprising filtering the noise of the environment of the speaker.

14. The method of claim 10, wherein the environment of the speaker comprises low noise.

15. The method of claim 14, wherein the selecting of one of the plurality of options comprises increasing the volume of the speaker.

16. The method of claim 10, wherein the environment of the listener comprises high noise.

17. The method of claim 10, wherein the environment of the listener comprises low noise.

18. The method of claim 9, wherein each of the options is configured to control the volume of the speaker and the volume of the listener.
